(19) United States
(12) Patent Application Publication
(10) Pub. No.: US 2023/0318565 A1
(43) Pub. Date: Oct. 5, 2023

(54) SAW DEVICE WITH TEMPERATURE COEFFICIENT OF FREQUENCY CORRECTION LAYER

(71) Applicant: Skyworks Solutions, Inc., Irvine, CA (US)

(72) Inventors: Rei Goto, Osaka-Shi (JP); Hironori Fukuhara, Ibaraki-Shi (JP)

(21) Appl. No.: 18/128,588

(22) Filed: Mar. 30, 2023

Related U.S. Application Data
(60) Provisional application No. 63/327,040, filed on Apr. 4, 2022.

(51) Int. Cl. H03H 9/02; H03H 9/145; H03H 9/25; H03H 9/64

(52) U.S. Cl. CPC H03H 9/02834; H03H 9/02559; H03H 9/02992; H03H 9/14541; H03H 9/25; H03H 9/6483

(57) ABSTRACT

A temperature coefficient of frequency compensated surface acoustic wave device is provided which includes: a piezoelectric substrate, an interdigital transducer configured to generate a surface acoustic wave in response to an electrical signal and a first temperature compensation layer disposed on the piezoelectric substrate, the interdigital transducer being disposed on the temperature compensation layer.

### INCORPORATION BY REFERENCE TO ANY PRIORITY APPLICATIONS

Any and all applications, if any, for which a foreign or domestic priority claim is identified in the Application Data Sheet of the present application are hereby incorporated by reference under 37 CFR 1.57.

### BACKGROUND

### Field

Embodiments of the invention relate to surface acoustic wave (SAW) devices with temperature coefficient of frequency correction, particularly to SAW devices with layers of silicon dioxide to correct the temperature coefficient of frequency of the Saw device.

### Description of the Related Technology

Simple SAW devices consist of a set of interleaved electrodes disposed at a first end of a piezoelectric substrate and a second set of interleaved electrodes disposed at a second end of the piezoelectric substrate. Surface acoustic waves are propagated by the transmitting electrodes, across the surface of the piezoelectric material, and then converted back from physical waves to electrical signals via the piezoelectric effect.

Prior art SAW devices are tuned to receive, or band-pass a particular frequency. This tuning is performed by selecting materials which make up the interdigital transducer (IDT) transmitter or receiver of the SAW device, or the piezoelectric substrate along which the waves pass.

However, these prior art SAW devices become inaccurate when the temperature of the device changes. This can occur when the device is implemented in an electronic circuit containing heat generating components. The temperature chance can change the band-pass of the filter. This means that the filter may tune into a different signal, or that signals need to be spaced far enough apart within the bandwidth of the carrier so that the margin of error of the SAW device does not matter. This problem therefore either decreases the reliability of the filter or wastes bandwidth of a carrier signal.

### SUMMARY

According to one embodiment there is provided a temperature coefficient of frequency compensated surface acoustic wave device, which includes: a piezoelectric substrate, an interdigital transducer configured to generate a surface acoustic wave in response to an electrical signal, and a first temperature compensation layer disposed on the piezoelectric substrate, the interdigital transducer being disposed on the temperature compensation layer.

The resonant frequency of a surface acoustic wave (SAW) filter is set to tune the filter to the particular frequency desired to be processed by the filter. It is therefore beneficial to ensure stability of the resonant frequency of the SAW filter. By providing a temperature compensation layer at the between a substrate and an interdigital transducer (IDT) of the filter, the drift caused by changes in temperature can be reduced and removed.

In one example the first temperature compensation layer is formed from Silicon Dioxide, SiO2. Silicon dioxide when disposed on the piezoelectric substrate and beneath the IDT can be advantageously tuned by modifying the thickness of the compensation layer, so that 0 temperature coefficient of frequency (TCF) is achieved at both the resonant and anti-resonant frequencies of the SAW device.

In one example the surface acoustic wave device further includes a second temperature compensation layer disposed beneath the piezoelectric substrate, and in a further example the second temperature compensation layer is formed from Silicon Dioxide, SiO2.

This layer allows for greater tuning of the TCF so that both the anti-resonant and resonant TCF can be altered to achieve zero TCF at both.

In one example the surface acoustic wave device further includes a silicon base layer disposed beneath the second temperature compensation layer.

In one example the piezoelectric substrate is formed from Lithium Niobate. In a further example the piezoelectric substrate is 20YX—LiNbO3. The Lithium Niobate structure allows for waves generated on the surface of the piezoelectric material to propagate across to an adjacent IDT. The rotated 20 degrees Y cut X propagation LiNbO3 is advantageous for the piezoelectric effect required for the SAW device to operate.

In one example the IDT is formed from aluminum. As the IDT physically creates waves across the surface of the SAW device, the physical properties of the wave generating device, which is an IDT, affects the wavelength of the waves propagated across the SAW device. Other metals can be used for the IDT, depending on the wavelength or frequency of signals required. Heavier IDTs can be used, which can shorten the wavelengths of the SAW device and therefore allow the SAW device to be minimized.

In one example the interdigital transducer comprises a pair of busbars disposed on opposite edges of the piezoelectric substrate.

In one example each busbar has a plurality of electrode fingers extending therefrom towards the opposing busbar.

In one example the electrode fingers of each busbar interleave with one another.

In one example the IDT includes a first layer and a second layer above the first layer. In a further example the first layer is formed from aluminum and in a further example the second layer is formed from any of one of tungsten, copper, gold, silver, platinum, ruthenium, molybdenum. By providing a two layer IDT it is possible to tune the IDT to achieve both zero TCF and also the wavelength required by the SAW device. By providing a heavier top layer the wavelength of the induced wave is reduced due to the physical inertia required to move the IDTs to generate waves. As there is a relationship between the wavelength of the SAW and the distance between IDT fingers, the device can be made smaller when the wavelength of the induced SAW is smaller.

In one example the distance from the centre of one electrode finger to the centre of the adjacent electrode finger has a length L, and in a further example the length L is equivalent to one wavelength of a wave propagated by the surface acoustic wave device. As noted above the relationship between wavelengths and the distance between IDTs is related. In this example, the relationship is such that one wavelength is propagated in the distance between matching sections of electrode fingers of the IDTs. That is, as the IDT is formed from interleaving fingers from opposing busbars, which are arranged such that along the length of the SAW device, the IDT is formed from adjacent fingers which are arranged a first finger from a first busbar then a second finger from the second busbar, then a third finger from the first busbar and so on. The SAW wavelength is equal to the distance from the first finger leading edge to the second finger leading edge, i.e. the SAW wavelength is equal to the width of an IDT and then the gap to the next IDT.

In one example the first temperature compensation layer is between 0.002 and 0.02 L in thickness. In this range the anti-resonant frequency TCFₚ drift stays approximately at zero percent, where the resonant frequency TCFₛ drift changes from round −10 to +5% drift. This can be considered acceptable for TCF drift for certain applications.

In one example the first temperature compensation layer is 0.008 L in thickness. This thickness allows for exactly 0% TCF drift at both resonant and anti-resonant frequencies.

In one example the second temperature compensation layer is approximately 0.4 L in thickness. In a further example the silicon base layer is greater than 2 L in thickness.

In one example the acoustic wave device further includes a passivation layer disposed between the temperature compensation layer and the interdigital transducer. The passivation layer provides mechanical protection for the temperature compensation layer.

According to another embodiment there is provided a method of reducing the temperature coefficient of frequency of a surface acoustic wave device comprising disposing a temperature compensation layer between a piezoelectric substrate and an interdigital transducer of the surface acoustic wave device.

According to another embodiment there is provided a filter, comprising: a plurality of low velocity surface acoustic wave devices, each of the plurality of low velocity surface acoustic wave devices including: a piezoelectric substrate, an interdigital transducer configured to generate a surface acoustic wave in response to an electrical signal, and a temperature compensation layer disposed on the piezoelectric substrate, the interdigital transducer being disposed on the temperature compensation layer.

According to another embodiment there is provided a front end module for installation in a wireless device, comprising a low velocity surface acoustic wave device, the low velocity surface acoustic wave device including: a piezoelectric substrate, an interdigital transducer configured to generate a surface acoustic wave in response to an electrical signal, and a temperature compensation layer disposed on the piezoelectric substrate, the interdigital transducer being disposed on the temperature compensation layer.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1a shows a prior art surface acoustic wave device.

FIG. 1b shows a representation of TCF drift in a prior art surface acoustic wave device.

FIG. 2 shows a surface acoustic wave device according to the present invention.

FIG. 3 shows a representation of TCF drift in the surface acoustic wave device according to the present invention.

FIG. 4 shows a representation of TCFₚ and TCFₛ with respect to thickness of a temperature compensation layer.

FIG. 5a shows an alternative surface acoustic wave device according to an aspect of the present invention.

FIG. 5b shows an alternative surface acoustic wave device according to an aspect of the present invention.

FIG. 5c shows an alternative surface acoustic wave device according to an aspect of the present invention.

FIG. 6 shows a representative IDT for use in a SAW device according to the present invention.

FIG. 7 shows an example of a ladder filter in which multiple low velocity SAW devices according to aspects of the present invention may be combined;

FIG. 8 is a block diagram of one example of a filter module that can include one or more low velocity SAW devices according to aspects of the present disclosure;

FIG. 9 is a block diagram of one example of a front-end module that can include one or more filter modules including low velocity SAW devices according to aspects of the present disclosure;

FIG. 10 is a block diagram of one example of a wireless device including the front-end module of FIG. 9.

### DETAILED DESCRIPTION

Aspects and embodiments described herein are directed to multi chip modules, particularly front end modules. In the following description, the term multi chip module (MCM) and front end module may be used interchangeably.

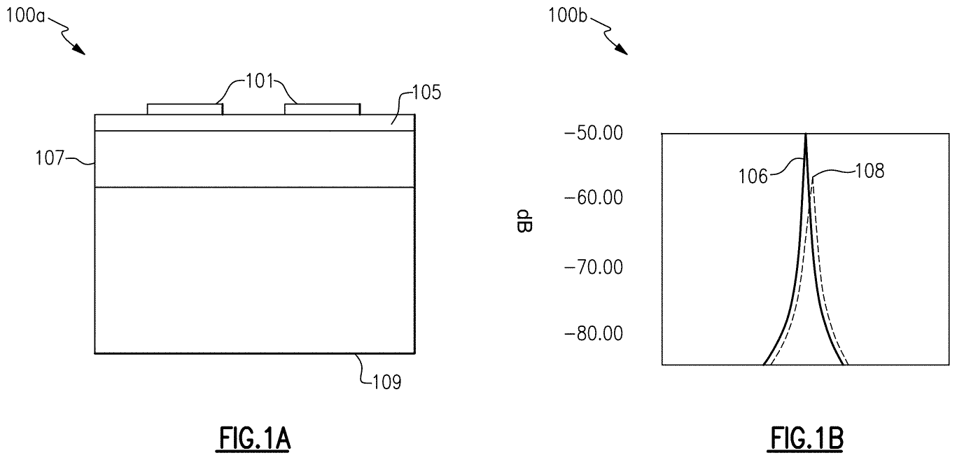

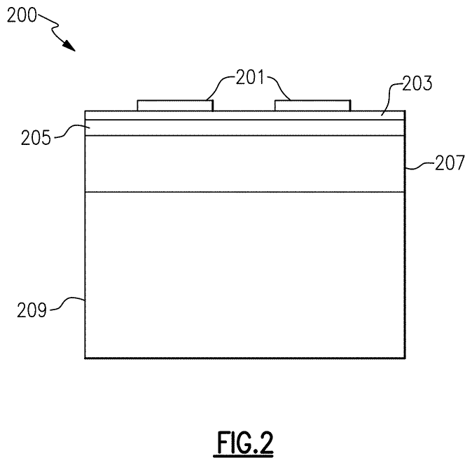

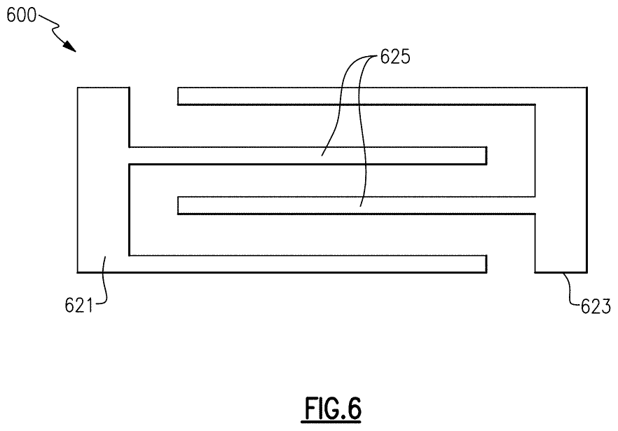

FIG. 1a shows a prior art surface acoustic wave (SAW) device 100a. The SAW device comprises a silicon base layer 109, a temperature compensation layer 107 disposed on the base layer 109, a piezoelectric substrate 105 disposed on the temperature compensation layer 107, and an IDT 101 disposed on the piezoelectric substrate 105. A representative plan view of an IDT is described with respect to FIG. 6, and it can be seen that the SAW device 100a is a cross sectional view taking through the center of the IDT 600.

The SAW device works as a filter by generating a signal at a first IDT and receiving that signal at a second IDT. The first IDT creates a physical wave in the piezoelectric substrate which is turned back into an electrical signal at the second IDT. The medium used to propagate the waves as well as the spacing between IDT fingers sets the passing frequency of the SAW device. Because of the physical properties of the device, and the physical manifestation of the RF waves, temperature can affect the resonant frequency of the device. As the temperature of the device increases, the physical properties of the piezoelectric substrate change, and thus the resonant frequency of the SAW device changes.

FIG. 1b shows the problem with this prior art SAW device 100a. The resonant frequency of the SAW device at 25° C. is shown by the line 106, and the resonant frequency of the SAW device 100 at 85° C. is shown by the line 108. In the chart 100b frequency is shown as the x axis and the attenuation in dB of the filter is shown on the y axis. As can be seen, with no mitigation of the effects of temperature on the resonant frequency of the SAW device 100, the resonant frequency drifts by a certain amount. In some examples this is approximately 3 MHz. This makes it difficult to tune the SAW device precisely, and means that the specific frequency passed by the device may change as the temperature of the device changes.

FIG. 2 shows a SAW device 200 according to one or more embodiments of the present invention. The SAW device 200 also includes a first temperature compensation layer 203 disposed between an IDT 201 and a piezoelectric substrate 205. The SAW device 200 also includes a second temperature compensation layer 207 disposed between the piezoelectric substrate 205 and the a silicon base layer 209.

The temperature compensation layer 203 can mitigate temperature drift from the SAW device at both the resonant and anti resonant frequencies.

The temperature compensation layer 203 can be applied to the substrate by chemical vapor deposition, atomic layer deposition, electron cyclotron resonance sputtering or radio frequency sputtering.

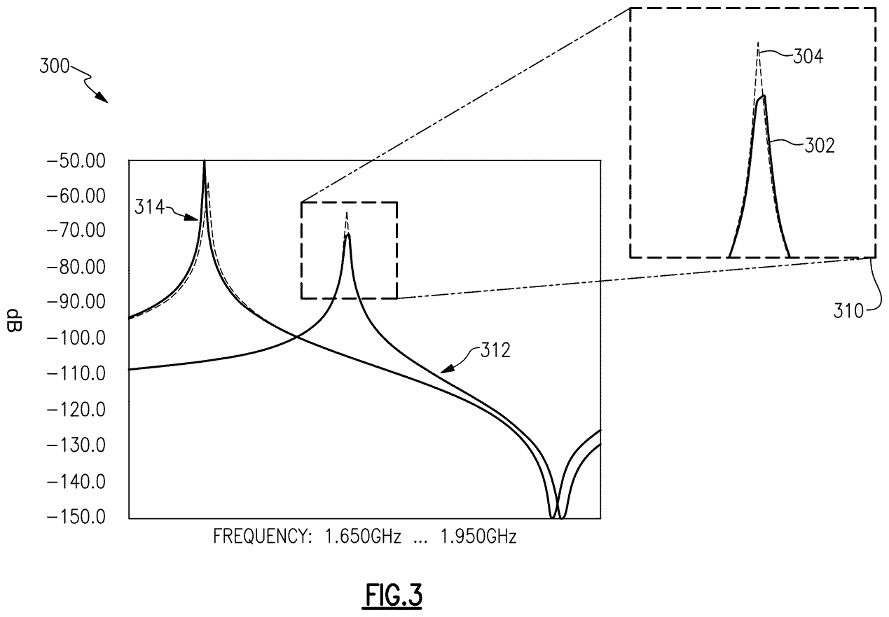

As can be seen in FIG. 3, and in contrast to the graph 100b in FIG. 1b, the temperature drift of the SAW device 200 is negligible. The graph 300 shows the prior art temperature drift 314 and the temperature drift 312 of the SAW device 200 according to the present invention, where the frequency of the filter response is shown on the x axis and the attenuation in dB is shown on the y axis.

As can be seen in the enlarged portion 310, there is little or no frequency drift between the resonant frequencies at 25° C., as shown by the line 302, and at 85° C., as shown by the line 304.

What can be seen is that the resonant frequency and anti-resonant frequency of the SAW device 200 is higher than that of the SAW device 100a, however this frequency change can be tunes out by adjusting the spacing of the IDTs.

It will be noted that there was little frequency drift at the anti-resonant frequencies of the SAW device, shown at the bottom of the chart 300 in either the prior art SAW device 100a or the improved SAW device 200. It will also be noted that the frequency response 312 of the improved SAW device 200 is more attenuated than the prior art device.

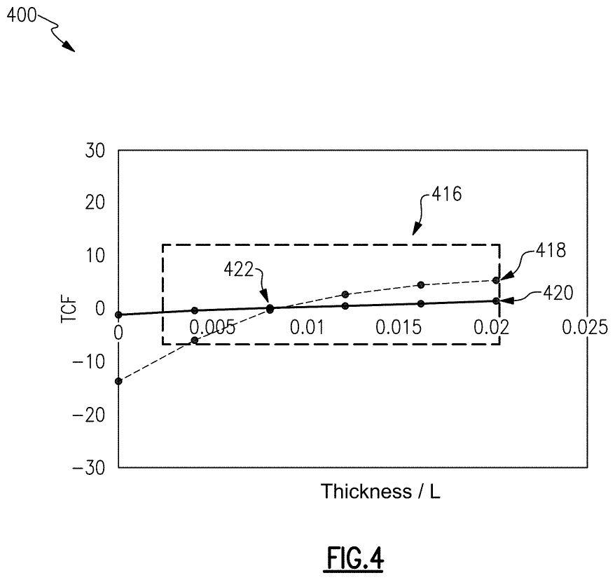

FIG. 4 shows in plot 400 how the TCF of the resonant 418 and anti-resonant 420 frequency drift can be tuned by adjusting the thickness of the temperature compensation layer 203. The thickness of the temperature compensation layer 203, shown on the x axis, is specified with respect to the wavelength (L) of a wave passed by the SAW device 200. The y axis denotes the TCF, where zero TCF represents no drift and any deviation below this line shifts the resonant frequency lower and any deviation above shifts the resonant frequency higher.

It can be seen that the TCFₚ or anti-resonant TCF, represented by line 420 stays largely at zero regardless of the thickness of the temperature compensation layer 203

By adjusting the thickness of the temperature compensation layer from 0 up to 0.02 L the TCFₛ or resonant frequency drift shown by line 418 changes from between −10 to 5, where zero is the aim. At around 0.08 L the “double zero” point 422 is met where both the resonant and anti-resonant frequency drift is 0, and thus the TCFz and TCFₚ are both 0. The window 416 represents the acceptable range of temperature compensation layer thickness to produce a workable SAW device.

In addition to the thickness of the temperature compensation layer 203, the other layers are specified in terms of thickness relative to the wavelength L, where the piezoelectric substrate 205 is approximately 0.4 L, the temperature compensation layer 207 is approximately 0.4 L thick and the silicon base layer is greater than 2 L thick.

A benefit of the invention over prior art solutions to the TCF problem is that the quality K\hat{ }2 metric of the filter is increased with respect to these prior art solutions K\hat{ }2 represents the coupling coefficient of the filter, where a higher number indicates better coupling of the IDTs of the SAW device. Typically, a non-stacked SAW device (i.e. one without multiple layers) which deals with TCF using the piezoelectric substrate materials may have a K\hat{ }2 of 8 to 9. This in comparison to a SAW device which does not mitigate against TCF but has a K\hat{ }2 of around 25 or more.

The SAW device 200 of the present invention, using the temperature compensation layer 203 achieves a K\hat{ }2 of 16 to 17, representing a significant improvement over the prior art.

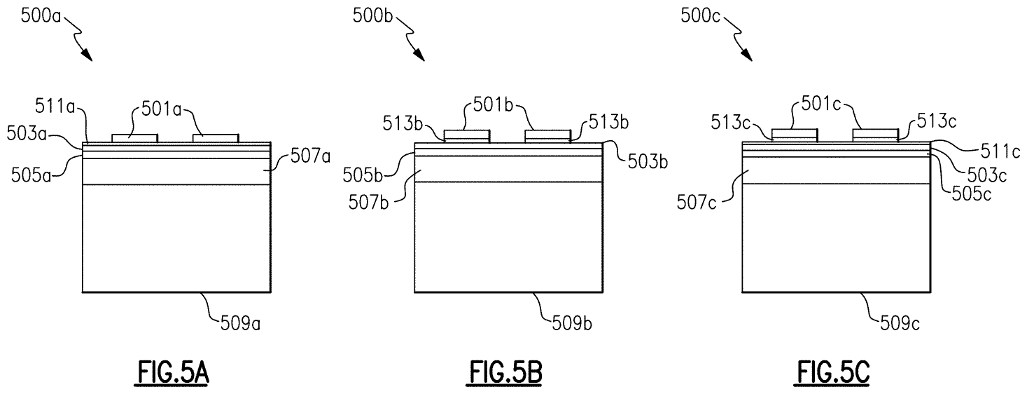

FIG. 5a shows a first modification 500a of the SAW device 200 which contains a passivation layer 511a disposed over the temperature compensation layer 503a. This provides mechanical and chemical protection to the SAW device 500a, which also contains the IDT 501a, piezoelectric substrate 505a, temperature compensation layer 507a and silicon base layer 509a. The passivation layer may also be disposed over the top of the IDT 501a, as opposed to under it as shown in FIG. 5a.

FIG. 5b shows a second modification 500b of the SAW device 200 which contains a two layer IDT, where the IDT has a top layer 501b made from a conventional IDT material such as aluminum, and a bottom layer 513b which is made from a different material such as tungsten or a lighter material than aluminum such as aluminum alloys. This allows for tuning of the frequency of the device, or indeed to make the device smaller by using shorter wavelength signals, because the velocity of the waves propagates by the SAW device 500b can be altered depending on the material used. The SAW device 500b also contains the temperature compensation layer 503b, piezoelectric substrate 505b, temperature compensation layer 507b and silicon base layer 509b.

This can optimally be used to tune out the resonant frequency change which is shown on FIG. 3, where the resonant frequency of the SAW device 200 is higher than the resonant frequency of the prior art SAW device 100a shown by line 314, cause by the temperature compensation layer 203.

FIG. 5c shows a shows a third modification 500c of the SAW device 200 which combines the features of the modified SAW devices 500a and 500b with an additional IDT layer 513c underneath IDT 501c and above a passivation layer 511c. The benefits of both modifications above below are compatible and provide a SAW device which is mechanically and chemically resistant and also can be miniaturized. The SAW device 500c also contains the temperature compensation layer 503c, piezoelectric substrate 505c, temperature compensation layer 507c and silicon base layer 509c.

FIG. 6 shows a plan view representation of an IDT 600 of the SAW device 200, analogous to the IDT 201 shown in side/cross sectional view FIG. 2. The IDT has two busbars, 621 and 623, with interleaved interdigital fingers 625 extending between each, alternately connected to each busbar. In practice, one busbar is connected to a signal and one to ground, or to the alternate side of the signal circuit. The IDT forms physical waves between the interdigital fingers 625 which are then propagated long the surface of the piezoelectric substrate, such as that shown in FIG. 2. A second IDT is disposed at a second end of the SAW device to receive these signals via the piezoelectric substrate and convert them back to electrical signals.

This means that the cross sectional views shown in FIGS. 1, 2 and 5 are short representations of a segment of a SAW device, which in practice would have many interdigital fingers 625 and two IDTs. In the above figures which denote embodiments according to the invention, it is intended that all areas of the SAW devices have the same qualities—i.e. the temperature compensation layer 203 extends along the entire length of the SAW device 200, under both sets of IDTs, and the two layer IDT of FIG. 5b is applied to all fingers of both IDTs on the SAW device 500b.

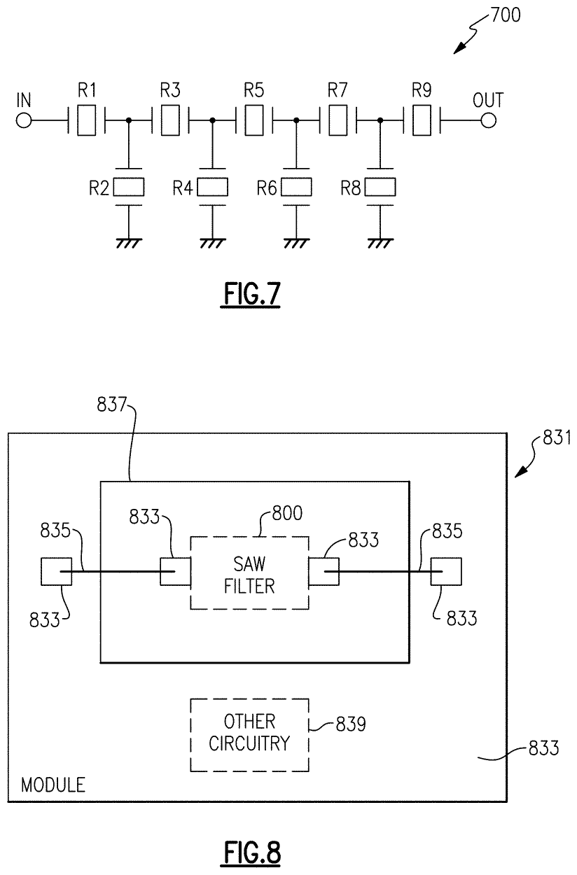

FIG. 7 shows an example of a filter 700 which multiple SAW resonators as disclosed herein may be combined. FIG. 13 shows an RF ladder filter 1300 including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW devices as disclosed herein.

Moreover, examples and embodiments of SAW devices discussed herein can be implemented in a variety of packaged modules. Some example packaged modules will now be discussed in which any suitable principles and advantages of the SAW resonators discussed herein can be implemented. FIGS. 8, 9 and 10 are schematic block diagrams of illustrative packaged modules and devices according to certain embodiments.

As discussed above, SAW devices, such as those of FIGS. 2 and 5A-C, can be used in SAW radio frequency (RF) filters. In turn, a SAW RF filter using one or more surface acoustic wave elements, such as the SAW device 700 of FIG. 7, may be incorporated into and packaged as a module that may ultimately be used in an electronic device, such as a wireless communications device, for example. FIG. 8 is a block diagram illustrating one example of a module 831 including a SAW device 800. The SAW device 800 may be implemented on one or more die(s) 837 including one or more connection pads 833. For example, the SAW device 800 may include a connection pad 833 that corresponds to an input contact for the SAW filter and another connection pad 833 that corresponds to an output contact for the SAW filter. The packaged module 831 includes a packaging substrate 832 that is configured to receive a plurality of components, including the die 837. A plurality of connection pads 834 can be disposed on the packaging substrate 832, and the various connection pads 833 of the SAW filter die 837 can be connected to the connection pads 834 on the packaging substrate 832 via electrical connectors 835, which can be solder bumps or wirebonds, for example, to allow for passing of various signals to and from the SAW device 800. The module 831 may optionally further include other circuitry die 839, for example, one or more additional filter(s), amplifiers, pre-filters, modulators, demodulators, down converters, and the like, as would be known to one of skill in the art of semiconductor fabrication in view of the disclosure herein. In some embodiments, the module 831 can also include one or more packaging structures to, for example, provide protection and facilitate easier handling of the module 831. Such a packaging structure can include an overmold formed over the packaging substrate 832 and dimensioned to substantially encapsulate the various circuits and components thereon.

Various examples and embodiments of the SAW device 800 can be used in a wide variety of electronic devices. For example, the SAW device 800 can be used in an antenna duplexer, which itself can be incorporated into a variety of electronic devices, such as RF front-end modules and communication devices.

Referring to FIG. 15, there is illustrated a block diagram of one example of a front-end module 940, which may be used in an electronic device such as a wireless communications device (e.g., a mobile phone) for example. The front-end module 940 includes an antenna duplexer 950 having a common node 941, an input node 945, and an output node 947. An antenna 960 is connected to the common node 941.

The antenna duplexer 950 may include one or more transmission filters 900a connected between the input node 945 and the common node 941, and one or more reception filters 900b connected between the common node 941 and the output node 947. The passband(s) of the transmission filter(s) are different from the passband(s) of the reception filters. Examples of the SAW device 800 can be used to form the transmission filter(s) 900a and/or the reception filter(s) 900b. An inductor or other matching component 943 may be connected at the common node 941.

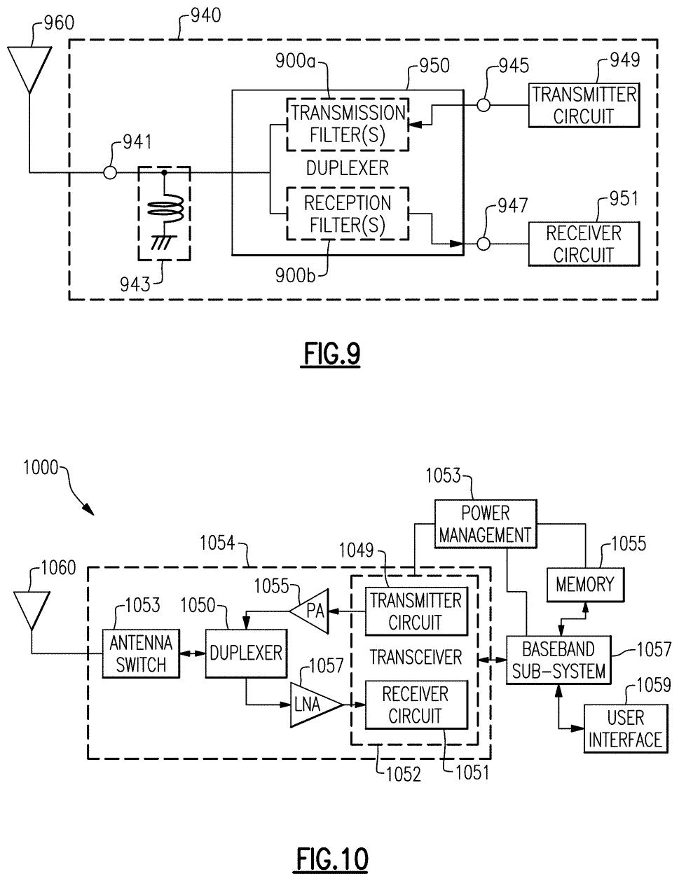

The front-end module 940 further includes a transmitter circuit 949 connected to the input node 945 of the duplexer 950 and a receiver circuit 951 connected to the output node 947 of the duplexer 950. The transmitter circuit 949 can generate signals for transmission via the antenna 960, and the receiver circuit 951 can receive and process signals received via the antenna 960. In some embodiments, the receiver and transmitter circuits are implemented as separate components, as shown in FIG. 9, however, in other embodiments these components may be integrated into a common transceiver circuit or module. As will be appreciated by those skilled in the art, the front-end module 940 may include other components that are not illustrated in FIG. 9 including, but not limited to, switches, electromagnetic couplers, amplifiers, processors, and the like.

FIG. 10 is a block diagram of one example of a wireless device 1000 including the antenna duplexer 1050 shown in FIG. 9. The wireless device 1000 can be a cellular phone, smart phone, tablet, modem, communication network or any other portable or non-portable device configured for voice or data communication. The wireless device 1000 can receive and transmit signals from the antenna 1060. The wireless device includes an embodiment of a front-end module 1040 similar to that discussed above with reference to FIG. 9. The front-end module 1040 includes the duplexer 1050, as discussed above. In the example shown in FIG. 10 the front-end module 1040 further includes an antenna switch 1053, which can be configured to switch between different frequency bands or modes, such as transmit and receive modes, for example. In the example illustrated in FIG. 10, the antenna switch 1053 is positioned between the duplexer 1050 and the antenna 1060; however, in other examples the duplexer 1050 can be positioned between the antenna switch 1053 and the antenna 1060. In other examples the antenna switch 1053 and the duplexer 1050 can be integrated into a single component.

The front-end module 1054 includes a transceiver 1052 that is configured to generate signals for transmission or to process received signals. The transceiver 1052 can include the transmitter circuit 1049, which can be connected to the input node of the duplexer 1050, and the receiver circuit 1051, which can be connected to the output node of the duplexer 1050, as shown in the example of FIG. 9.

Signals generated for transmission by the transmitter circuit 1049 are received by a power amplifier (PA) module 1055, which amplifies the generated signals from the transceiver 1052. The power amplifier module 1055 can include one or more power amplifiers. The power amplifier module 1055 can be used to amplify a wide variety of RF or other frequency-band transmission signals. For example, the power amplifier module 1055 can receive an enable signal that can be used to pulse the output of the power amplifier to aid in transmitting a wireless local area network (WLAN) signal or any other suitable pulsed signal. The power amplifier module 1055 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 1055 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 10, the front-end module 1040 may further include a low noise amplifier (LNA) module 1057, which amplifies received signals from the antenna 960 and provides the amplified signals to the receiver circuit 951 of the transceiver 930.

The wireless device 1000 of FIG. 10 further includes a power management sub-system 1053 that is connected to the transceiver 1052 and manages the power for the operation of the wireless device 1000. The power management system 1053 can also control the operation of a baseband sub-system 1057 and various other components of the wireless device 1000. The power management system 1053 can include, or can be connected to, a battery (not shown) that supplies power for the various components of the wireless device 1000. The power management system 1020 can further include one or more processors or controllers that can control the transmission of signals, for example. In one embodiment, the baseband sub-system 1057 is connected to a user interface 1059 to facilitate various input and output of voice and/or data provided to and received from the user. The baseband sub-system 1057 can also be connected to memory 1055 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

Further examples of the electronic devices that aspects of this disclosure may be implemented include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A surface acoustic wave device, comprising:
a piezoelectric substrate;
an interdigital transducer configured to generate a surface acoustic wave in response to an electrical signal; and
a first temperature compensation layer disposed on the piezoelectric substrate, the interdigital transducer being disposed on the first temperature compensation layer.

2. The surface acoustic wave device of claim 1 wherein the first temperature compensation layer is formed from Silicon Dioxide, SiO2.

3. The surface acoustic wave device of claim 1 further comprising a second temperature compensation layer disposed beneath the piezoelectric substrate.

4. The surface acoustic wave device of claim 3 wherein the second temperature compensation layer is formed from Silicon Dioxide, SiO2.

5. The surface acoustic wave device of claim 3 wherein the first temperature compensation layer is between 0.002 and 0.02 L in thickness.

6. The surface acoustic wave device of claim 3 wherein the first temperature compensation layer is 0.008 L in thickness.

7. The surface acoustic wave device of claim 5 wherein the second temperature compensation layer is approximately 0.4 L in thickness.

8. The surface acoustic wave device of claim 7 further comprising a silicon base layer disposed beneath the second temperature compensation layer.

9. The surface acoustic wave device of claim 1 wherein the piezoelectric substrate is formed from Lithium Niobate.

10. The surface acoustic wave device of claim 9 wherein the piezoelectric substrate is 20YX—LiNbO3.

11. The surface acoustic wave device of claim 1 wherein the interdigital transducer is formed from Aluminum.

12. The surface acoustic wave device of claim 1 wherein the interdigital transducer includes a first layer and a second layer above the first layer, the first layer is formed from Aluminum, and the second layer is formed from any of one of tungsten, copper, gold, silver, platinum, ruthenium, or molybdenum.

13. The surface acoustic wave device of claim 12 further comprising a second temperature compensation layer disposed beneath the piezoelectric substrate.

14. The surface acoustic wave device of claim 13 wherein a thickness of the second temperature compensation layer is greater than the thickness of the first temperature compensation layer.

15. The surface acoustic wave device of claim 1 wherein the interdigital transducer includes a pair of busbars disposed on opposite edges of the piezoelectric substrate, each busbar has a plurality of electrode fingers extending therefrom towards an opposing busbar, and the plurality of electrode fingers of the busbars interleave with one another.

16. The surface acoustic wave device of claim 15 wherein a distance from a center of one electrode finger to a center of an adjacent electrode finger has a length L that is equivalent to one wavelength of a wave propagated by the surface acoustic wave device.

17. The surface acoustic wave device of claim 16 further comprising a silicon base layer greater than 2 L in thickness disposed below the first temperature compensation layer.

18. The surface acoustic wave device of claim 1 further comprising a passivation layer disposed beneath the first temperature compensation layer and the interdigital transducer.

19. A filter, comprising: a plurality of low velocity surface acoustic wave devices, each of the plurality of low velocity surface acoustic wave devices including:
a piezoelectric substrate;
an interdigital transducer configured to generate a surface acoustic wave in response to an electrical signal; and
a temperature compensation layer disposed on the piezoelectric substrate, the interdigital transducer being disposed on the temperature compensation layer.

20. A front end module for installation in a wireless device, comprising a low velocity surface acoustic wave device, the low velocity surface acoustic wave device including:
a piezoelectric substrate;
an interdigital transducer configured to generate a surface acoustic wave in response to an electrical signal; and
a temperature compensation layer disposed on the piezoelectric substrate, the interdigital transducer being disposed on the temperature compensation layer.
